(19) United States
(12) Patent Application Publication
(10) Pub. No.: US 2002/0102847 A1
(43) Pub. Date: Aug. 1, 2002

(54) MOCVD-grown InGaAsN using efficient and novel precursor, tertibutylhydrazine, for optoelectronic and electronic device applications

(76) Inventors: Paul R. Sharps, Albuquerque, NM (US); Hong Qi Hou, Albuquerque, NM (US); Nein-Yi Li, Sunnyvale, CA (US); Ravi Kanjolia, North Andover, MA (US)

Correspondence Address: WHITE & CASE LLP, PATENT DEPARTMENT, 1155 AVENUE OF THE AMERICAS, NEW YORK, NY, 10036, US

(21) Appl. No.: 09/956,540

(22) Filed: Sep. 17, 2001

Related U.S. Application Data
(60) Provisional application No. 60/233,565, filed on Sep. 19, 2000.

(51) Int. Cl. H01L 21/20; H01L 21/36; H01L 21/44

(52) U.S. Cl. 438/681; 438/483; 438/485; 438/503

(57) ABSTRACT

TBHy is demonstrated as an efficient and a less carbon-containing N precursor for the growth of high-quality InGaAsN by MOCVD at lower growth temperatures. The photovoltaic characteristics of 1.20 eV InGaAsN solar cells, such as open-circuit voltage, short-circuit current, fill factor and efficiency are improved significantly by using TBHy compared to using DMHy. This demonstration can also be applied to other InGaAsN-based optoelectronic and electronic devices. Therefore, this invention is extremely important to expedite the demonstration of next-generation prototype products such as 1.3 μm-InGaAsN-epitaxial VCSELs for high-speed optical communications, low-power Npn InGaP/InGaAsN/GaAs HBTs and InGaP/AlGaAs/InGaAsN HEMTs for wireless applications, and high-efficiency multiple-junction InGaP/GaAs/InGaAsN/Ge solar cells for space power systems.

### PRIORITY

Pursuant to 35 U.S.C. § 119(e) and 37 C.F.R. § 1.78, the present application claims priority to the provisional application entitled “MOCVD-Grown InGaAsN Using Efficient And Novel Precursor, Tertibutylhydrazine, For Optoelectronic And Electronic Device Applications” by Paul R. Sharps et al. (application Ser. No. 60/233,565; attorney docket number 1613370-0003) filed on Sep. 18, 2000.

### BACKGROUND OF THE INVENTION

Recently, a semiconductor alloy, InₓGa₁₋ₓAs_{1-y}N_{y}, which can be lattice matched or strained to GaAs, has shown a great potential for next-generation optoelectronic and electronic device applications; such as (1) 1.3 μm vertical-cavity surface-emitting lasers (VCSELs) for future low-cost and high-capacity optical fiber communications (M. C. Larson et al., IEEE Photonics Technol. Lett. 10, 188 (1998)), (2) high-efficiency multiple-junction (InGaP/GaAs/InGaAsN/Ge) solar cells for advanced space systems (H. Q. Hou et al., 2^{nd} World Conference and Exhibition Photovoltaic Solar Energy Conversion, Jul. 6-10, 1998, Vienna, Austria, p. 3600 (1998)), (3) Npn InGaP/InGaAsN/GaAs heterojunction bipolar transistors (HBTs) (N. Y. Li et al., Electron. Lett. 36, 81 (2000)) and enhanced-mode high electron mobility transistors (HEMTs) using InGaAsN as the channel for low-cost and low-power wireless electronic devices. (A. G. Baca et al., USA Patent Pending)

Therefore, growth of high-quality InGaAsN becomes the key technology to have InGaAsN-based VCSELs solar cells, HBTs, and HEMTs realized for low-cost, high-volume markets in the near future. Currently, dimethylhydrazine (DMHy) has been commonly used as the nitrogen (N) source for InGaAsN growth by metalorganic vapor phase epitaxy (MOCVD). Generally speaking, a low-temperature growth and a much higher DMHy/AsH₃ (Arsine) flow rate ratio are necessary to incorporate enough N into InGaAs by MOCVD. However, incomplete pyrolysis of DMHy at low growth temperatures usually introduces carbon impurities from methyl-ligand in DMHy into InGaAsN epilayers, resulting in a higher background carrier concentration. In addition, a much higher DMHy flow is required to maintain a high flow rate ratio of DMHy/AsH₃ for InGaAsN growth, making DMHy not practical and economical for low-cost mass production, especially for high-efficiency quadruple-junction InGaAsN solar cells.

### SUMMARY OF THE INVENTION

An efficient precursor, tertiarybutylhydrazine (TBHy) is proposed as the N source in this invention to solve problems mentioned above for the growth of high-quality lattice-matched and strained InGaAsN for applications of solar cells, HBTs, HEMTs, and VCSELs. The presence of tert-butyl group, a stable free radical, is likely to reduce carbon incorporation.

### BRIEF DESCRIPTION OF THE DRAWINGS

The accompany drawings, which are incorporated in and constitute a part of this specification, illustrate several embodiments of the invention and, together with the description, serve to explain the principles of the invention

FIG. 1 is a graph illustrating the room-temperature PL spectra of InGaAsN/GaAs quantum wells according to one embodiment of the present invention;

FIG. 2 is a graph illustrating room-temperature Pl of two InGaAsN/GaAs quantum wells grown with TBHy according to one embodiment of the present invention,

FIG. 3a is an illustration of the chemical structure of the precursor DMHy; and

FIG. 3b is an illustration of the chemical structure of the precursor TBHy according to one embodiment of the invention.

### DESCRIPTION OF THE INVENTION

The first single junction 1.2 eV In_{0 03}Ga_{0.97}As_{0.99}N_{0.01} solar cell has been demonstrated at Emcore Photo Voltaics, Emcore Corporation. The layer structure of this device is shown in Table 1. The inactive InGaP top cell was grown on the top of InGaAsN bottom cell as the filter layer. The 1.20 eV In_{0.03}Ga_{0.97}As_{0.99}N_{0.01} solar cell was grown by an Emcore D180 turbodisk reactor. Trimethylindium, triethylgallium (TEGa), 100% AsH₃, and TBHy were used as the In, Ga, As, and N precursors, respectively, for the growth of a 0.2 μm-thick InGaAsN emitter and a 0.9 μm-thick InGaAsN base layers. To get lattice-matched In_{0.03}Ga_{0.97}As_{0.99}N_{0.01} epitaxial layers grown on GaAs, the flow rate ratio of TBHy/(TBHy+AsH₃) is fixed a 0.35, which is much lower than the flow rate ratio of DMHy/(DMHy+AsH₃) at 0.95. For the growth of bulk InGaAsN at a growth rate of 8 Å/s and an AsH₃ flow of 25 sccm, the consumption rate of TBHy is ˜6 gram/m, while that of DMHy is 41 gram/μm. The consumption rate ratio of DMHy/TBHy is almost up to 7, indicating TBHy is a very efficient N precursor for InGaAsN growth.

TABLE 1
Layer Structure of 1.20 eV InGaAsN Solar Cell

| 1.20 eV InGaAsN | | | |
|---|---|---|---|
| Solar Cells | Material | Thickness [Å] | Doping [cm⁻³] |
| Contact Layer | N⁺ GaAs | 5000 | 5 E ± 18 |
| Filter Layer | N⁺ In_{0.5}Ga_{0.5}P | 6200 | 3 E ± 18 |
| Window Layer | N⁺ In_{0.5}Ga_{0.5}P | 500 | 2 E ± 18 |
| Emitter Layer | n InGaAsN | 1000 | 2 E ± 18 |
| Emitter Layer | n InGaAsN | 1000 | 1 E ± 18 |
| Base Layer | p⁻InGaAsN | 9000 | Undoped: 2 E ± 17 |
| BSF layer #2 | p-GaAs | 50 | 2 E ± 18 |
| BSF layer #1 | p-Al_{0.3}Ga_{0.7}As | 200 | 2 E ± 18 |
| Buffer Layer | p⁺GaAs | 3000 | 2 E ± 19 |
| Substrate | P⁺-GaAs | | |

Table 2 shows the electrical characteristics of 1.20 eV InGaAsN solar cells, measured under simulated AM0 illumination. Samples 1 and 2 were grown at 584 and 614° C. using TBHy and DMHy as the N source, respectively. The cell size is 1 cm², and the cells had no anti-reflection coating. Sample 1 grown with TBHy shows a higher open-circuit voltage (V_{oc}), short-circuit current (I_{SC}), fill factor (FF), and efficiency than Sample 2 with DMHy. Besides, the secondary ion mass spectroscopy (SIMS) analysis shows that the carbon (C) concentration in undoped InGaAsN grown with TBHy is slightly lower than that of Sample 2. Usually [C] in an epilayer increases significantly with decreasing T_{g}, SIMS results confirm that TBHy incorporates less carbon in the low-temperature InGaAsN growth. The C concentration in InGaAsN grown with TBHy can be further reduced by increasing T_{g}, therefore the crystalline quality of InGaAsN can be improved.

TABLE 2
Comparisons of 1.2 eV InGaAsN solar
cells grown with TBHy and DMHy

| | Voc | | FF | Efficiency | | | |
|---|---|---|---|---|---|---|---|
| | (mV) | I_{SC} (mA/cm²) | (%) | (%) | [C] cm⁻³ | N | Tg (° C.) |
| Sample | 690 | 11.25 | 73.6 | 4.2 | 2.0E + 17 | TBHy | 584 |
| 1 | | | | | | | |
| Sample | 581 | 10.7 | 59.8 | 2.7 | 3.2E + 17 | DMHy | 614 |
| 2 | | | | | | | |

TABLE 3
shows other test results comparing 1.25 eV
InGaAsN solar cells grown with DMHy vs. TBHy.

| | VP | T_{g} | |
|---|---|---|---|
| DMHy | 162 Torr @ 25° C. | 539° C. with TMGa, | DHMz/(DMHZ + TBA) = |
| | | TMIn, TEGa, TBA, | 0.98 |
| | | TDMASb | |
| TBHy | 7 Torr @ 25° C. | 519° C. with TMGa, | TBHy/(TBHy + |
| Better uniformity | | TMIn, TEGa, TBA, | AsH3) = 0.41-0.71 |
| more efficient and | | TDMASb | |
| less likely for carbon | | | |
| incorporation | | | |
| Higher T_{g} & V/III | | | |

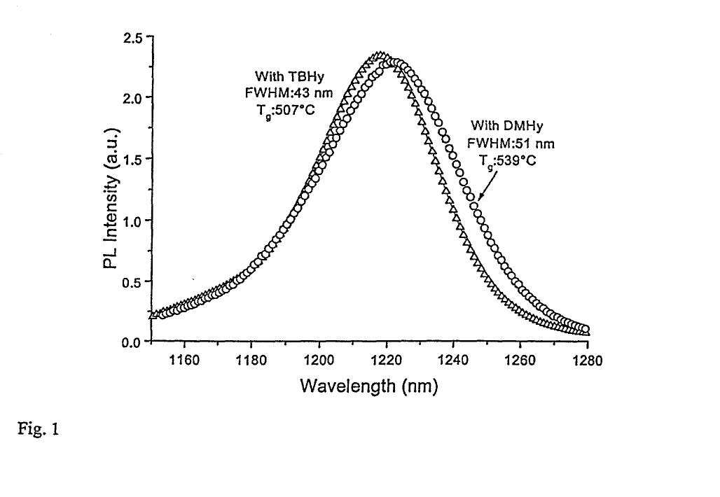

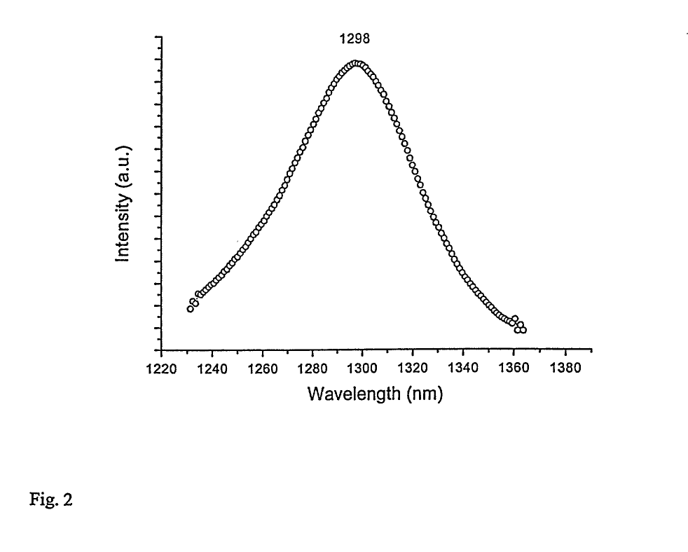

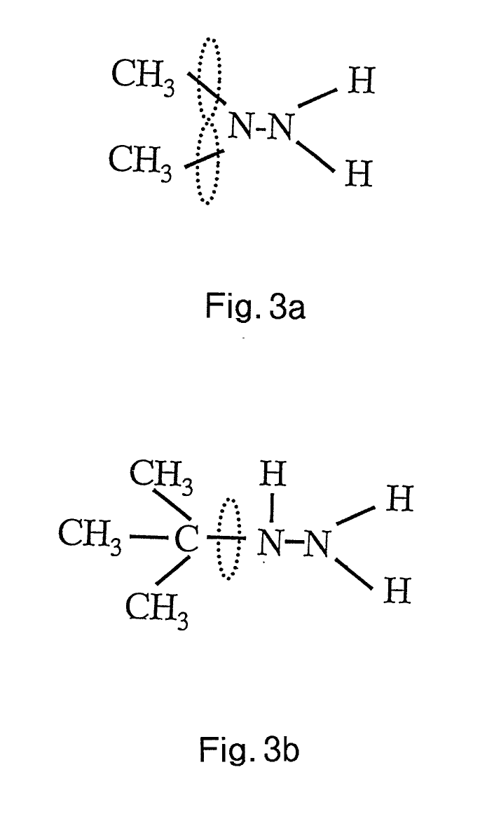

Strained InGaAsN as the quantum wells of 1.22 and 1.30 μm edge emitting laser and as the channel of InGaP/AlGaAs/InGaAsN HEMT has be grown with TBHy. FIG. 1 illustrates room temperature PL spectra of two In_{0.03}Ga_{0.97}As_{0.99}N_{0.01}/GaAs quantum wells (QWs) grown with TBHy and DMHy. FIG. 2 illustrates room-temperature PL of two InGaAsN/GaAs grown with TBHy. FIG. 3 compares the chemical of DMHy (CH₃)₂NNH₂ and TBHy (CH₃)₃CNHNH₂.

As shown in FIG. 1, the PL wavelength of two InGaAsN/GaAs QWs grown with TBHy and DMHy are observed at 1.220 and 1.224 μm with a full width at half maximum (FWHM) of 43 and 51 nm, respectively, indicating InGaAsN QWs grown with TBHy has a better crystalline quality than that grown with DMHy. By increasing the flow rate ratio of TBHy/AsH₃ from 0.56 to 2.40, it has been successfully demonstrated room-temperature 1.3 μm PL shown in FIG. 2. Based on these results, it is seen that TBHy is a more efficient and a less carbon-containing N precursor for growth of high-quality InGaAsN.

By using the efficient and less carbon-containing TBHy as the N source, not only the cost of MOCVD-grown InGaAsN can be effectively reduced, but also the material quality of InGaAsN can be significantly improved.

The present invention has shown a great commercial potential for next generation optoelectronic and electronic products, such as 1.3μm-InGaAsN-epitaxial VCSELs, low-power Npn InGaP/InGaAsN/GaAs HBTs, AlGaAs/InGaAsN HEMTs, and high-efficiency multiple-junction InGaP/GaAs/InGaAsN/Ge solar cells. This invention is critical to meeting the demanding of the low-cost III-V compound semiconductor markets in the near future.

What is claimed is:

1. A method for metal organic chemical vapor deposition (MOCVD) comprising the step of growing InGaAsN using tertiarybutylhydrazine (TBHy) as a nitrogen (N) precursor.

2. The method as recited in claim 1 further comprising the step of growing said InGaAsN using trimethylindium as an indium (In) precursor.

3. The method as recited in claim 1 further comprising the step of growing said InGaAsN using triethylgallium (TEGa) as a gallium (Ga) precursor.

4. The method as recited in claim 1 further comprising the step of growing said InGaAsN using arsine (AsH₃) as an arsenic (As) precursor.

5. A method for metal organic chemical vapor deposition (MOCVD) comprising the step of growing InGaAsN using a nitrogen (N) precursor that has a tert-butyl group.

6. A method for metal organic chemical vapor deposition (MOCVD) comprising the step of growing InGaAsN using a nitrogen (N) precursor that has a lower carbon incorporation tendency than dimethylhydrazine (DMHy).

7. A semiconductor alloy InGaAsN produced by a method for metal organic chemical vapor deposition (MOCVD), said method comprising the step of growing said InGaAsN using tertiarybutylhydrazine (TBHy) as a nitrogen (N) precursor.

8. A semiconductor alloy InₓGa₁₋ₓAs_{1-y}N_{y} produced by a method for metal organic chemical vapor deposition (MOCVD), said method comprising the step of growing said InₓGa₁₋ₓAs_{1-y}N_{y} using tertiarybutylhydrazine (TBHy) as a nitrogen (N) precursor.

9. A solar cell comprising an epitaxial layer of InGaAsN wherein said InGaAsN is produced by a method for metal organic chemical vapor deposition (MOCVD), said method comprising the step of growing said InGaAsN using tertiarybutylhydrazine (TBHy) as a nitrogen (N) precursor.

10. The solar cell as recited in claim 9 which is a multiple-junction InGaP/GaAs/InGaAsN/Ge solar cell.

11. A vertical-cavity surface-emitting laser (VCSEL) device comprising InGaAsN wherein said InGaAsN is produced by a method for metal organic chemical vapor deposition (MOCVD), said method comprising the step of growing said InGaAsN using tertiarybutylhydrazine (TBHy) as a nitrogen (N) precursor.

12. The VCSEL as recited in claim 11 which comprises an InGaAsN/GaAs quantum well.

13. A hetero-junction bipolar transistor (HBT) comprising InGaAsN wherein said InGaAsN is produced by a method for metal organic chemical vapor deposition (MOCVD), said method comprising the step of growing said InGaAsN using tertiarybutylhydrazine (TBHy) as a nitrogen (N) precursor.

14. The HBT as recited in claim 13 which is an InGaP/InGaAsN/GaAs HBT.

15. A high electron mobility transistor (HEMT) comprising an InGaAsN channel wherein said InGaAsN is produced by a method for metal organic chemical vapor deposition (MOCVD), said method comprising the step of growing said InGaAsN using tertiarybutylhydrazine (TBHy) as a nitrogen (N) precursor.

16. The HEMT as recited in claim 15 which is an AlGaAs/InGaAsN HEMT.

17. An optoelectronic device comprising InGaAsN wherein said InGaAsN is produced by a method for metal organic chemical vapor deposition (MOCVD), said method comprising the step of growing said InGaAsN using tertiarybutylhydrazine (TBHy) as a nitrogen (N) precursor.

18. An electronic device comprising InGaAsN wherein said InGaAsN is produced by a method for metal organic chemical vapor deposition (MOCVD), said method comprising the step of growing said InGaAsN using tertiarybutylhydrazine (TBHy) as a nitrogen (N) precursor.
